(19) United States
(12) Patent Application Publication
(10) Pub. No.: US 2024/0388106 A1
(43) Pub. Date: Nov. 21, 2024

(54) PRINTED CIRCUIT BOARD, AND BATTERY MANAGEMENT SYSTEM AND BATTERY PACK INCLUDING THE SAME

(71) Applicant: SAMSUNG SDI CO., LTD., Yongin-si (KR)

(72) Inventor: Jin Cheol Bae, Yongin-si (KR)

(21) Appl. No.: 18/496,510

(22) Filed: Oct. 27, 2023

(30) Foreign Application Priority Data
May 19, 2023 (KR) 10-2023-0065163

(51) Int. Cl. H02J 7/00; H01Q 1/24; H04B 1/18; H05K 1/02

(52) U.S. Cl. CPC H02J 7/00036; H01Q 1/24; H04B 1/18; H05K 1/0243

(57) ABSTRACT

A printed circuit board of the present disclosure includes a first surface, a second surface that is substantially parallel to the first surface, a pattern antenna on the first surface, a first trace for transferring a signal between a radio frequency integrated circuit on the first surface and the pattern antenna, and a fill-cut pattern on the second surface and covering the first trace, wherein the fill-cut pattern is formed by removing a portion of a first ground pattern in a line shape corresponding to the first trace.

### CROSS-REFERENCE TO RELATED APPLICATION

The present application claims priority to and the benefit of Korean Patent Application No. 10-2023-0065163, filed on May 19, 2023, in the Korean Intellectual Property Office, the entire disclosure of which is incorporated herein by reference.

### BACKGROUND

### 1. Field

The present disclosure relates to a printed circuit board, and to a battery management system and a battery pack including the same.

### 2. Description of the Related Art

A secondary battery, which may be repeatedly charged and discharged, differs from a primary battery, which instead provides only irreversible conversion of chemical energy to electrical energy. A low-capacity secondary battery is used as a power supply for a small electronic device, such as a mobile phone, a laptop computer, or a camcorder, and a high-capacity secondary battery is used as a power supply for a hybrid vehicle or the like.

In general, a secondary battery cell includes an electrode assembly including a positive electrode, a negative electrode, and a separator interposed between the positive electrode and the negative electrode, a case accommodating the electrode assembly, and an electrode terminal electrically connected to the electrode assembly. An electrolyte solution is injected into the case to enable charging and discharging of the battery cell through an electrochemical reaction between the positive electrode, the negative electrode, and the electrolyte solution. A shape of the case, such as a cylindrical or rectangular shape varies depending on a use of the battery cell.

Battery cells may be connected in series and/or in parallel to form a battery module with high energy density. A battery pack may include one or more of battery modules according to a suitable specification.

The battery pack includes a battery management system (BMS) for monitoring, controlling, and/or setting the battery pack. The BMS may include a battery system manager (BSM) operating as a master control device, a battery management module (BMM) operating as a slave control device, and a battery disconnect unit (BDU) that blocks or allows a connection between the battery pack and an external device depending on a function. The BMM measures and balances states (e.g., a voltage, a temperature, a current, and the like) of the cells included in the battery module, and transmits state information, event occurrence information, and the like detected in the process to the BSM that is the master.

There has recently been an increasing number of cases where the control devices inside the battery pack are designed to communicate using wireless communication. For example, the BMM is designed to measure a cell voltage, a module voltage, a temperature, or the like and then transmit the measurement result to the BSM through wireless communication.

On the other hand, for the BMM to communicate with the BSM wirelessly, an antenna that transmits and receives a wireless signal may be suitable. To secure robustness of wireless communication by increasing transmission output and reception sensitivity of the wireless signal, the antenna that transmits and receives the wireless signal has to be designed to match a suitable frequency band.

The BMS is often manufactured by mounting components included in the BMS circuit on a flexible printed circuit board (PCB). Typically, a rigid PCB may have a thickness of about 1 mm to about 1.6 mm, and may include a plurality of dielectric layers and a plurality of copper layers between top and bottom surfaces thereof. The dielectric layer may be designed to have a sufficient thickness to enable an antenna pattern and a circuit design in each layer. On the other hand, the flexible PCB has a structure in which it may be difficult to secure a sufficient thickness of the dielectric layer. Therefore, an antenna mounted on the flexible PCB is mainly mounted on the PCB in the form of a chip or a surface mount device (SMD). However, if an antenna component having the form of the chip or the surface mount device (SMD) is used, there may be a problem in which frequency-band matching using the antenna component is difficult or impossible.

### SUMMARY

The present disclosure provides a printed circuit board that may solve a problem in which it may be difficult to match a frequency band of an antenna that implements a battery management system with a wireless communication function using a flexible printed circuit board (PCB), and provides the battery management system and a battery pack including the printed circuit board.

A printed circuit board according to embodiments includes a first surface, a second surface that is substantially parallel to the first surface, a pattern antenna on the first surface, a first trace for transferring a signal between a radio frequency integrated circuit on the first surface and the pattern antenna, and a fill-cut pattern on the second surface and covering the first trace, wherein the fill-cut pattern is formed by removing a portion of a first ground pattern in a line shape corresponding to the first trace.

The printed circuit board may further include a matching circuit region on the first surface, and in which an impedance-matching circuit for adjusting a frequency band to which the pattern antenna is matched through impedance matching is mounted, and a second trace passing through the matching circuit region on the first surface for transferring a signal between the first trace and the pattern antenna, wherein the first trace functions as a signal transfer between the radio frequency integrated circuit and the impedance-matching circuit.

The fill-cut pattern may cover the second trace.

The pattern antenna may include an antenna body, and a signal transfer pattern protruding from the antenna body, and having a wire shape connected to the second trace.

A width of the fill-cut pattern may be wider than a width of the first trace.

At least a portion of the pattern antenna may be connected to the first ground pattern.

The printed circuit board may further include a second ground pattern on the first surface, and spaced apart from the first trace to surround the first trace in plan view. A conductive pattern may be not at a region corresponding to the pattern antenna on the second surface.

The printed circuit board may further include at least one via hole adjacent the fill-cut pattern for impedance matching.

The printed circuit board may include a flexible printed circuit board.

A battery management system according to embodiments includes the printed circuit board, the radio frequency integrated circuit, and an impedance-matching circuit for adjusting a frequency band to which the pattern antenna is matched through impedance matching, wherein the radio frequency integrated circuit and the impedance-matching circuit are connected to the pattern antenna by the first trace and a second trace.

A battery pack according to embodiments includes a battery module and the battery management system above.

According to the present disclosure, if a battery management system with wireless communication function using a flexible printed circuit board (PCB) is implemented, a problem in which it is difficult to match frequency band of an antenna may be resolved.

### BRIEF DESCRIPTION OF THE DRAWINGS

FIG. 1 is a structural diagram schematically showing a battery pack according to embodiments.

FIGS. 2A to 2G each show a pattern antenna according to embodiments.

FIG. 3 shows a matching circuit of a battery management system according to embodiments.

FIG. 4 shows a flexible printed circuit board (PCB) of a battery management system according to embodiments.

FIG. 5A is an enlarged view of a portion of an upper surface radio frequency (RF) block of the flexible printed circuit board of FIG. 4.

FIG. 5B is an enlarged view of a portion of a lower surface RF block of the flexible printed circuit board of FIG. 4.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a printed circuit board according to embodiments, and a battery management system and a battery pack including the same will be described in detail with reference to necessary drawings.

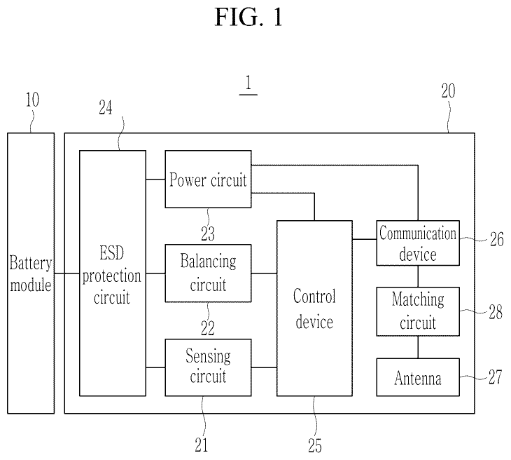

FIG. 1 is a structural diagram schematically showing the battery pack according to embodiments.

Referring to FIG. 1, the battery pack 1 may include a battery module 10 and a battery management system (BMS) 20.

The battery module 10 may include a plurality of battery cells connected in series and/or in parallel.

The BMS 20 may include a sensing circuit (or a detection circuit) 21, a balancing circuit 22, a power circuit (or a power supply circuit) 23, a control device 25, a communication device 26, an antenna (e.g., pattern antenna) 27, and a matching circuit (e.g., impedance-matching circuit) 28.

The sensing circuit 21 may detect a cell voltage, a module voltage, a temperature, or the like from the battery module 10, and may transfer the detection result to the control device 25.

The balancing circuit 22 may perform a balancing function between the battery cells of the battery module 10 under a control of the control device 25.

The power circuit 23 may receive the module voltage supplied from the battery module 10, and may use the received module voltage to supply driving power for driving the control device 25 and the communication device 26 that will be described later.

The BMS 20 may further include an electrostatic discharge (ESD) protection circuit 24 located between the battery module 10 and at least one of the sensing circuit 21, the balancing circuit 22, or the power circuit 23. The ESD protection circuit 24 may perform a function of protecting the BMS from an ESD and/or a surge flowing into the BMS 20 from the outside.

The control device 25 may obtain state information (e.g., the cell voltage, the module voltage, the temperature, or the like) of the battery module 10 through the sensing circuit 21, and may perform state diagnosis of the battery module 10 based on the state information. The control device 25 may transmit the state information, diagnosis information, or the like, which is detected from the battery module 10, to an upper controller through wireless communication. The control device 25 may control a balancing of the battery module 10 by controlling the balancing circuit 22 based on the state information of the battery module 10. For example, the control device 25 may include an analog front end (AFE) integrated circuit (IC).

The communication device 26 and the antenna 27 may be used for wireless communication between the control device 25 and the upper controller.

The communication device 26 may transmit and receive a wireless signal of a frequency band (e.g., a predetermined frequency band) through the antenna 27 to communicate with the upper controller. The communication device 26 may transmit information received from the control device 25 to the upper controller through the antenna 27. The communication device 26 may transfer a signal received from the upper controller through the antenna 27 to the control device 25. For example, the communication device 26 may include a radio frequency (RF) IC.

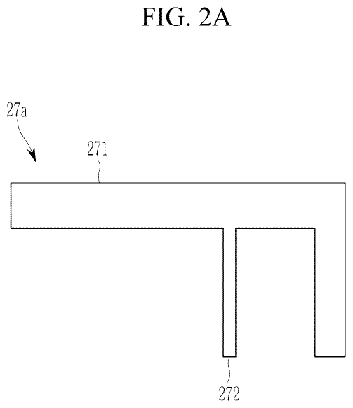

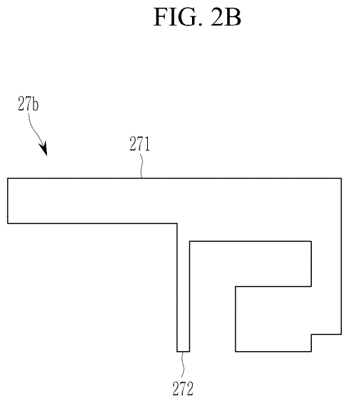

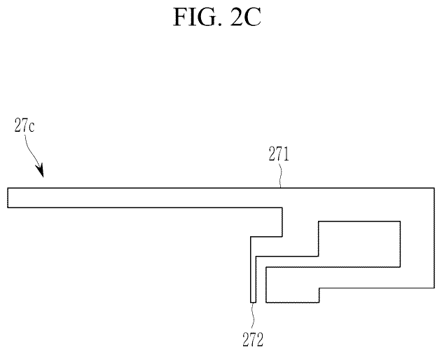

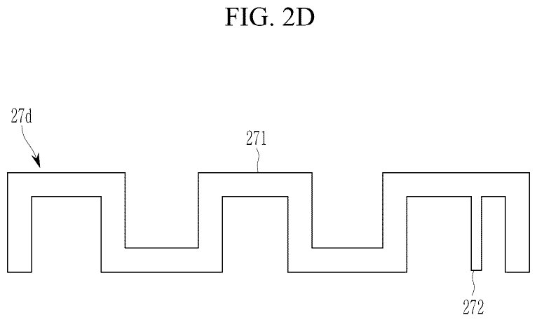

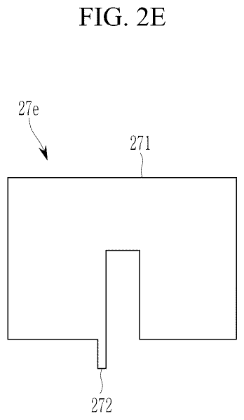

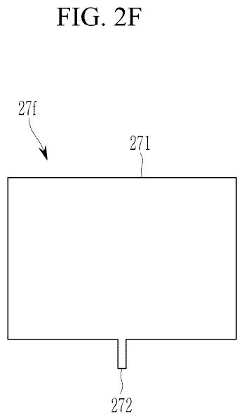

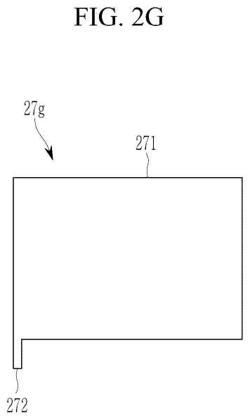

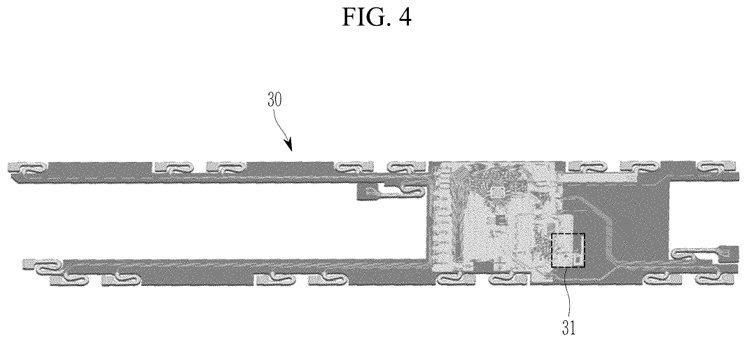

The antenna 27 may radiate a signal received from the communication device 26 as a wireless signal, and/or may receive a wireless signal transmitted from the upper controller to transfer the received signal to the communication device 26. The antenna 27 may be configured in the form of a pattern antenna that is patterned using a conductive material on one surface of a printed circuit board (PCB) 30 of FIG. 4 on which the BMS 20 is mounted. FIGS. 2A to 2G show examples of the antenna 27 implemented as the pattern antenna.

Referring to FIGS. 2A to 2D, the antenna 27a, 27b, 27c, or 27d may include an antenna body 271 that is bent one or more times, and a wire-shaped signal transfer pattern 272 protruding from the antenna body 271. For example, the antenna 27a of FIG. 2A may include an F-shaped antenna pattern, and the pattern antennas 27b and 27c of FIGS. 2B and 2C may include a shape that is slightly modified from the F-shaped antenna 27a of FIG. 2A. In some embodiments, the antenna 27d of FIG. 2D may have a shape in which one end portion of the F-shaped antenna 27a of FIG. 2A is extended, and the extended portion may include a serpentine shape by repeatedly bending the extended portion.

Referring to FIGS. 2E to 2G, the antenna 27e, 27f, or 27g may include a planar-shaped antenna body 271 and a wire-shaped signal transfer pattern 272 protruding from the antenna body 271.

Like the embodiments shown in FIGS. 2A to 2G, a pattern shape, a pattern area, a pattern width, or the like of the antenna 27 may be variously modified. For example, in FIGS. 2A to 2D, the antenna body 271 of the antenna 27 may be bent 1 time (see FIG. 2A), may be bent 2 times (see FIGS. 2B and 2C), and may be bent 10 times (see FIG. 2D), but various modifications are possible in a direction in which the antenna body 271 is bent, the number of times the antenna body 271 is bent, and the like. For example, the signal transfer pattern 272 may be a straight-wire shape shown in FIGS. 2A, 2B, and 2D to 2G, or may be a bent wire shape shown in FIG. 2C.

The antenna 27 may be patterned on the PCB with a metal or an alloy material depending on a suitable electrical conductivity, a suitable electrical property, or a suitable mechanical property, such as ductility or the like. For example, the antenna 27 may be formed by patterning an antenna pattern of a corresponding shape on one surface of the PCB using a metal material, such as copper, tin, silver, gold, or the like.

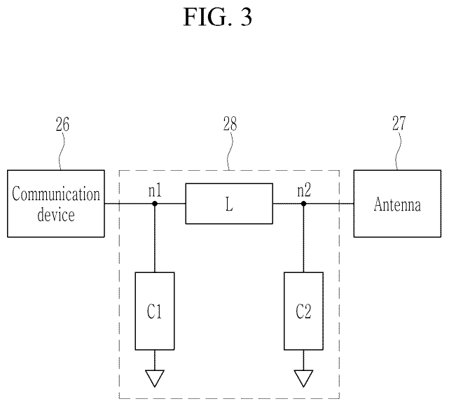

Referring back to FIG. 1, the matching circuit 28 may be connected between the communication device 26 and the antenna 27. FIG. 3 shows an example of the matching circuit 28. For example, the matching circuit 28 may include an inductor L connected on a signal transfer path between the communication device 26 and the antenna 27, may include a capacitor C1 connected between a ground and a node n1 that is between the communication device 26 and the inductor L, and may include a capacitor C2 connected between a ground and a node n2 that is between the inductor L and the antenna 27.

The matching circuit 28 may function to adjust the antenna 27 to match a suitable communication frequency band by matching impedances seen from an input side and an output side of the matching circuit 28. For example, the matching circuit 28 may function to compensate for a characteristic of the antenna 27 being deteriorated due to a characteristic of the flexible printed circuit board (PCB) if the antenna 27 is coupled to the flexible PCB. For example, the antenna 27 on one surface of the flexible PCB may be formed so that a frequency of the antenna 27 matches a frequency band near the suitable communication frequency band (e.g., a 2.4 GHz band), and the matching circuit 28 may precisely adjust an impedance so that the frequency of the antenna 27 closely matches a center frequency of the suitable communication frequency band (e.g., about 2.44 GHZ).

The BMS 20 may further include the flexible PCB 30 of FIG. 4 on which components that are the sensing circuit 21, the balancing circuit 22, the power circuit 23, the ESD protection circuit 24, the control device 25, the communication device 26, the antenna 27, and the matching circuit 28 are mounted. The sensing circuit 21, the balancing circuit 22, the power circuit 23, the ESD protection circuit 24, the control device 25, the communication device 26, the antenna 27, and the matching circuit 28 of the BMS 20 may be mounted on the flexible PCB 30, and may be mounted within the battery pack 1.

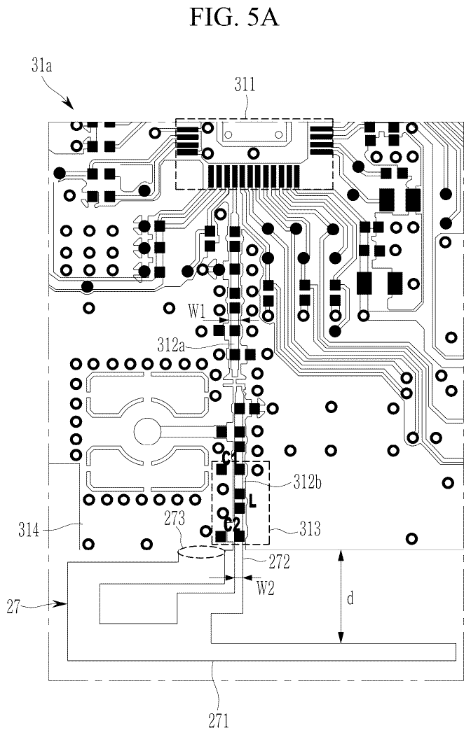

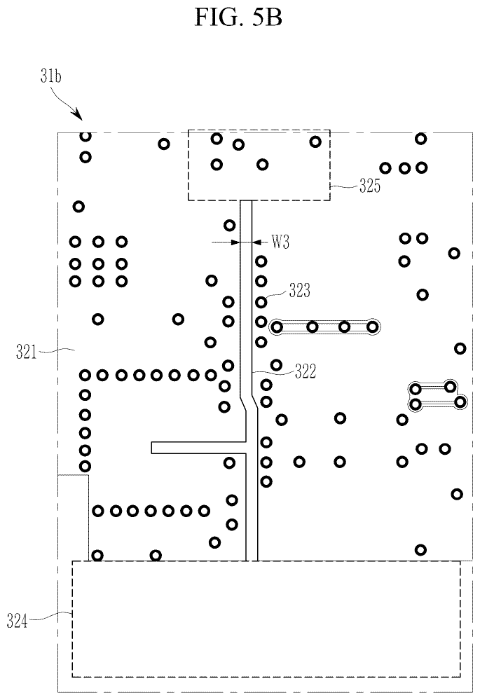

FIG. 4 shows an example of the flexible PCB of the BMS 20 according to embodiments. FIGS. 5A and 5B are enlarged views of a portion 31 of the flexible PCB of FIG. 4 that is a portion of a region where a radio frequency (RF) block for wireless communication is located, and show an upper surface 31a and a lower surface 31b, respectively.

Referring to FIGS. 4, 5A, and 5B, a plurality of components that include a radio frequency integrated circuit (RFIC) included in the communication device 26, the inductor L and the capacitors C1 and C2 included in the matching circuit 28, and the like, may be mounted on the upper surface 31a of the flexible PCB 30, and the antenna 27 may be on the upper surface 31a of the flexible PCB 30.

Referring to FIG. 5A, traces 312a and 312b for transferring a signal between the radio frequency integrated circuit and the antenna 27 may be between the antenna 27 and a region 311 where the radio frequency integrated circuit is coupled on the upper surface 31a of the flexible PCB 30. The trace 312a may be a signal transfer wire connected between the communication device 26 including the radio frequency integrated circuit and the matching circuit 28, and may be a straight-line shape that is not bent. The trace 312b may be a signal transfer wire connected between the trace 312a and the antenna 27, and may pass through a region 313 where the matching circuit 28 is mounted. A width W1 of the trace 312a or 312b may be determined for the impedance matching.

A ground pattern (e.g., second ground pattern) 314 may be around the traces 312a and 312b to surround the traces 312a and 312b (e.g., in plan view), and the ground pattern 314 may be spaced apart from the traces 312a and 312b by an interval (e.g., a predetermined interval, for example, about 0.15 mm).

The antenna 27 may be on the upper surface 31a of the flexible PCB 30. The signal transfer pattern 272 of the antenna 27 may be connected to the trace 312b. In one or more embodiments, a signal between the antenna 27 and the radio frequency integrated circuit may be transferred through the signal transfer pattern 272 of the antenna 27 and the traces 312a and 312b. The signal transfer pattern 272 of the antenna 27 may have the same width W2 as that of the trace 312a or 312b.

The antenna 27 may be formed so that at least a portion of the pattern antenna is connected to a ground. Referring to FIG. 5A, a portion 273 of the antenna 27 may be connected to the ground pattern 314. The antenna 27 may ensure a sufficient distance (e.g., about 5.8 mm or more) d between the ground pattern 314 and one end portion of the pattern antenna not connected to the ground pattern 314 to avoid interference. In the present specification, the ground pattern may refer to a conductor layer connected to a ground.

Referring to FIG. 5B, to improve matching performance for the communication frequency band, the flexible PCB 30 may include a fill-cut pattern 322. The fill-cut pattern 322 may be on the lower surface 31b of the flexible PCB 30. The fill-cut pattern 322 may be a pattern in which a portion of a ground pattern (e.g., first ground pattern) 321 on the lower surface 31b of the flexible PCB 30 is removed in a line shape. That is, the fill-cut pattern 322 may be a pattern in which a portion of a bare board of the flexible PCB 30 is exposed to the outside in a line shape. The fill-cut pattern 322 may be on the lower surface 31b of the flexible PCB 30 between a region 325 that corresponds to the radio frequency integrated circuit and a region 324 that corresponds to the antenna 27. The fill-cut pattern 322 may be on the lower surface 31b in a region corresponding to a region where the traces 312a and 312b of the upper surface 31a are to thereby cover a region where the traces 312a and 312b are. A width W3 of the fill-cut pattern 322 may be wider than the width W1 of the trace 312a or 312b so that the entire traces 312a and 312b may be covered by the fill-cut pattern 322. For example, if the width W1 of the trace 312a or 312b is about 0.5 mm, the width W3 of the fill-cut pattern 322 may be about 0.75 mm.

To further improve matching performance for the communication frequency band, the flexible PCB 30 may further include a plurality of via holes 323 adjacent to the fill-cut pattern 322. For example, the region 324 corresponding to the antenna 27 may be formed so as not to dispose any conductive pattern (e.g., a ground pattern) on the lower surface 31b of the flexible PCB 30.

Even though the BMS 20 is configured using the flexible PCB 30 in the battery pack 1, precise frequency matching is possible using the antenna 27 and the matching circuit 28 on one surface of the flexible PCB 30, the fill-cut pattern 322 on the other surface of the flexible PCB 30, and the plurality of via holes 323 around the fill-cut pattern 322. Therefore, by improving matching performance for the suitable communication frequency band, wireless communication performance (e.g., transmission output and reception sensitivity) of the BMS 20 may be improved, and robustness of the wireless communication may be secured.

Electronic or electrical devices according to embodiments of the present disclosure and/or other related devices or constituent elements may be realized by using appropriate hardware, firmware (e.g., an application-specific integrated circuit), software, or combinations of software, firmware, and hardware. For example, various configurations of the above-noted devices may be positioned on one integrated circuit (IC) chip or an individual IC chip. In one or more embodiments, various configurations of the above-noted devices may be realized on a flexible printed circuit film, a tape carrier package (TCP), a printed circuit board (PCB), or one substrate. The electrical or mutual connections described in the present specification may, for example, be realized by the PCB, wires on different types of circuit carriers, or conductive elements. The conductive elements may, for example, include metallization, such as surface metallizations and/or pins, and may include conductive polymers or ceramics.

In one or more embodiments, the various configurations of the devices may be performed by at least one processor so as to perform the above-described various functions, they may be performed in at least one computing device, and they may be processes or threads for performing computer program instructions and interacting with other system constituent elements. The computer program instruction is stored in a memory realizable in a computing device using a standard memory device, such as a random access memory (RAM). The computer program instruction may also be stored in a non-transitory computer readable medium, such as a CD-ROM or a flash drive.

Further, a person of ordinary skill in the art must understand that various functions of the computing device may be combined or united to a single computing device, or functions of a specific computing device may be dispersed to at least another computing device while not digressing from the range of the embodiments of the present disclosure.

### DESCRIPTION OF SOME OF THE REFERENCE CHARACTERS

| | | |
|---|---|---|
| 1: battery pack | 10: battery module | 20: battery management |
| | | system |
| 21: sensing circuit | 22: balancing circuit | 23: power circuit |
| 24: ESD protection | 25: control unit | 26: communication |
| circuit | | device |
| 27, 27a-27g: antenna | 28: matching circuit | 30: flexible PCB |
| 312a, 312b: trace | 322: fill-cut pattern | 323: via hole |
| 314, 321: ground pattern | | |

What is claimed is:

1. A printed circuit board comprising:
a first surface;
a second surface that is substantially parallel to the first surface;
a pattern antenna on the first surface;
a first trace for transferring a signal between a radio frequency integrated circuit on the first surface and the pattern antenna; and
a fill-cut pattern on the second surface and covering the first trace,
wherein the fill-cut pattern is formed by removing a portion of a first ground pattern in a line shape corresponding to the first trace.

2. The printed circuit board as claimed in claim 1, further comprising:
a matching circuit region on the first surface, and in which an impedance-matching circuit for adjusting a frequency band to which the pattern antenna is matched through impedance matching is mounted; and
a second trace passing through the matching circuit region on the first surface for transferring a signal between the first trace and the pattern antenna,
wherein the first trace functions as a signal transfer between the radio frequency integrated circuit and the impedance-matching circuit.

3. A battery management system comprising:
the printed circuit board as claimed in claim 2;
the radio frequency integrated circuit; and
the impedance-matching circuit,
wherein the radio frequency integrated circuit and the impedance-matching circuit are connected to the pattern antenna by the first trace and the second trace.

4. A battery pack comprising:
a battery module; and
the battery management system as claimed in claim 3.

5. The printed circuit board as claimed in claim 2, wherein the fill-cut pattern covers the second trace.

6. A battery management system comprising:
the printed circuit board as claimed in claim 5;
the radio frequency integrated circuit; and
the impedance-matching circuit,
wherein the radio frequency integrated circuit and the impedance-matching circuit are connected to the pattern antenna by the first trace and the second trace.

7. A battery pack comprising:
a battery module; and
the battery management system as claimed in claim 6.

8. The printed circuit board as claimed in claim 2, wherein the pattern antenna comprises:
an antenna body; and
a signal transfer pattern protruding from the antenna body, and having a wire shape connected to the second trace.

9. A battery management system comprising:
the printed circuit board as claimed in claim 8;
the radio frequency integrated circuit; and
the impedance-matching circuit,
wherein the radio frequency integrated circuit and the impedance-matching circuit are connected to the pattern antenna by the first trace and the second trace.

10. A battery pack comprising:
a battery module; and
the battery management system as claimed in claim 9.

11. The printed circuit board as claimed in claim 1, wherein a width of the fill-cut pattern is wider than a width of the first trace.

12. The printed circuit board as claimed in claim 1, wherein at least a portion of the pattern antenna is connected to the first ground pattern.

13. The printed circuit board as claimed in claim 1, further comprising a second ground pattern on the first surface, and spaced apart from the first trace to surround the first trace in plan view.

14. A battery management system comprising:
the printed circuit board as claimed in claim 13;
the radio frequency integrated circuit; and
an impedance-matching circuit for adjusting a frequency band to which the pattern antenna is matched through impedance matching,
wherein the radio frequency integrated circuit and the impedance-matching circuit are connected to the pattern antenna by the first trace and a second trace.

15. A battery pack comprising:
a battery module; and
the battery management system as claimed in claim 14.

16. The printed circuit board as claimed in claim 1, wherein a conductive pattern is not at a region corresponding to the pattern antenna on the second surface.

17. A battery management system comprising:
the printed circuit board as claimed in claim 16;
the radio frequency integrated circuit; and
an impedance-matching circuit for adjusting a frequency band to which the pattern antenna is matched through impedance matching,
wherein the radio frequency integrated circuit and the impedance-matching circuit are connected to the pattern antenna by the first trace and a second trace.

18. A battery pack comprising:
a battery module; and
the battery management system as claimed in claim 17.

19. The printed circuit board as claimed in claim 1, further comprising at least one via hole adjacent the fill-cut pattern for impedance matching.

20. The printed circuit board as claimed in claim 1, wherein the printed circuit board comprises a flexible printed circuit board.
